(19) United States
(12) Patent Application Publication
(10) Pub. No.: US 2009/0002033 A1
(43) Pub. Date: Jan. 1, 2009

(54) Noise removal circuit and comparator circuit including same

(75) Inventors: Shinji Nakatani, Okazaki-city (JP); Nobukazu Oba, Okazaki-city (JP); Norikazu Ohta, Aichi-gun (JP); Hideki Hosokawa, Owariasahi-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/213,893

(22) Filed: Jun. 26, 2008

(30) Foreign Application Priority Data
Jun. 29, 2007 (JP) 2007-171710

(51) Int. Cl. H03K 5/22

(52) U.S. Cl. 327/73

(57) ABSTRACT

The present invention reliably removes a signal change associated with a noise component from a comparison signal of a comparator. A comparator circuit includes a comparator and a timer circuit. After a reversal of the comparison signal, if the level of the comparator is sustained at least from a first time to a second time, an output signal is reversed and output. The timer circuit includes a memory unit that is shifted to a memory state in which the reversal of the comparison signal is stored at the first time if the reversal is verified. If the comparison signal is reversed during the interval between the first time and second time, the memory state is cleared.

### CROSS-REFERENCE TO RELATED APPLICATIONS

The present application is based on and claims priority to Japanese Application No. JP 2007-171710 filed on Jun. 29, 2007, the entire contents of which are incorporated herein by reference.

### BACKGROUND OF THE INVENTION

1. Field of the Invention

The present invention relates to a noise removal circuit that removes a signal change associated with a noise component from a comparison signal outputted from a comparator and more particularly to a comparator circuit including the noise removal circuit.

2. Description of the Related Art

An example of a comparator circuit that has been developed can include, for example, a binary-coding circuit that compares an analog input signal V_{IN} shown in FIG. 15A with a threshold V_{REF}, and generates and output signal V_{OUT} at times t1 and t3 that is reversed in polarity or level, such as from a low level to a high level or from a high level to a low level, when the analog input signal V_{IN} exceeds the threshold V_{REF}. The output signal is reversed back to the original level at the times t2 and t4 when the analog input signal V_{IN} falls below threshold V_{REF}.

The above described binary-coding circuit includes a comparator. The analog input signal V_{IN} is applied to one terminal of the comparator, and the threshold V_{REF} is applied to the other terminal of the comparator. An output of the comparator is reversed in polarity or level when the analog input signal V_{IN} exceeds the threshold V_{REF} and is re-reversed when the analog input signal V_{IN} falls below the threshold V_{REF}. The comparator therefore outputs an output signal V_{OUT} shown in FIG. 15B. Once the output signal V_{OUT} is obtained, the number of reversals can be counted, and the frequency of the analog input signal V_{IN} can be measured.

A pulsating high-frequency noise component is often superposed on the analog input signal V_{IN}. FIG. 15C shows the analog input signal V_{IN} in enlargement, and shows an example in which a pulsating high-frequency noise component is superposed on an increasing analog input signal V_{IN1}.

When the analog input signal V_{IN} on which a noise component is superposed is inputted to the comparator, the output signal V_{OUT} of the comparator repeats, as shown in FIG. 15C, a reversal/re-reversal phenomenon can be attributed to the noise component. Therefore, once the noise component is superposed on the analog input signal V_{IN}, the output signal V_{OUT} of the comparator exhibits a chattering as shown in FIG. 15D. Once the output signal V_{OUT} exhibits a chattering, it becomes impossible to measure the frequency of the analog input signal V_{IN} by counting the number of reversals.

A technology has been developed for discriminating a signal change associated with a noise component superposed on the analog input signal V_{IN1} in terms of a time width, and an example is described in JP-A-10-282132. A time-base filter is used for the purpose of removing a signal change associated with a noise component. The time-base filter includes digital filters. Specifically, a high-frequency clock signal is used to discretely sample a comparison signal of a comparator on a time base, and a decision is made regarding the state of the comparison signal of the comparator according to the discrete-time sequential data items. For example, when the comparison signal of the comparator is reversed from a low level to a high level, if multiple discrete-time sequential data items demonstrate that the comparison signal of the comparator sustains the high level, a decision is made that the reversal is a typical signal change exhibited by the comparison signal of the comparator but is not a signal change associated with a noise component. The digital filters of JP-A-10-282132 are configured to remove the signal change associated with the noise component from the comparison signal of the comparator.

The time-base filter in JP-A-10-282132 is used to make decisions regarding the comparison signal of the comparator according to discrete-time sequential data items obtained by using a high-frequency clock signal. However, when a high-frequency clock signal is used to obtain discrete-time sequential data items, a signal change associated with a noise component having as high or a higher frequency than the high-frequency clock signal then the signal change due to noise may not be accurately reflected in the discrete-time sequential data items. For example, when a signal change associated with a noise component occurs at intervals of a sampling cycle, the time-base filter in JP-A-10-282132 may allow a decision to be made that the comparison signal of the comparator is sustained at the same level over the period of time. Consequently, the time-base filter in JP-A-10-282132 may not be able to accurately remove the signal change associated with a noise component, from the comparison signal of the comparator.

The above description is made based on the assumption that the noise component to be superposed on the analog input signal is a pulsating high-frequency noise component. However, a high-frequency surge noise component may be superposed on the analog input signal. The surge noise component poses the same technical problems as the pulsating high-frequency noise component. It should be noted that in the present specification, a noise component refers to a component that should be discriminated from a typical signal change in the comparison signal of the comparator. For the purposes of the present discussion, a noise component can include a pulsating high-frequency noise component and a high-frequency surge noise component and the various embodiments discussed and described herein will apply broadly to noise components.

### SUMMARY OF THE INVENTION

An object of the present is to reliably remove a signal change associated with a noise component from a comparison signal of a comparator by using an analog technical idea instead of the technical idea of digital filters.

The present application includes similarities to the technology described in JP-A-10-282132 in that a time width is used to discriminate a signal change associated with a noise component, from a comparison signal of a comparator. However, it should be understood that in accordance with the present specification the comparison signal of the comparator is not discretely sampled and a decision is not made on the state of the comparison signal of the comparator according to discrete-time sequential data items. Instead, in accordance with various embodiments described herein associated with the invention, the comparison signal of the comparator is continuously monitored. Therefore, after the comparison signal of the comparator is reversed, if the comparison signal of the comparator is re-reversed during at least a predetermined period of time, the fact is regarded as a sufficient condition in order to decide that the signal has undergone a signal change associated with a noise component. In the related art, even if a comparison signal of a comparator is re-reversed due to a noise component, unless evidenced in discrete-time sequential data items, a decision cannot be made that the reversal is a signal change associated with a noise component. On the other hand, in accordance with various exemplary embodiments, since re-reversal of the comparison signal of the comparator is considered as a sufficient condition, the signal change associated with the noise component can be accurately discriminated from the comparison signal of the comparator. Eventually, the signal change associated with the noise component can be reliably removed from the comparison signal of the comparator. Further, if a noise removal circuit using the technology is combined with the comparator, a comparator circuit capable of accurately binary-coding an analog input signal can be produced.

The invention can be embodied in a noise removal circuit that removes a signal change associated with a noise component from a comparison signal outputted from a comparator that inputs a first input signal and a second input signal. The noise removal circuit includes a timer circuit that inputs the comparison signal of the comparator, and verifies that the comparison signal has been reversed from a low level to a high level and/or from the high level to the low level at the first time and the second time later than the first time. After the comparison signal is reversed from the low level to the high level and/or from the high level to the low level, if the level is sustained from the first time to the second time, an output signal is reversed between the low level and high level, and then outputted. The timer circuit includes a memory means that is shifted, set, or the like, to a memory state in which, when the comparison signal has been reversed from the low level to the high level and/or from the high level to the low level at the first time is verified, the reversal is stored. When the comparison signal of the comparator is reversed during the interval between the first time and second time, the memory state is changed, cleared, or the like, to remove the indication of the reversal. In the timer circuit, the time width from the first time to the second time is designated so that the signal change associated with a noise component can be discriminated from the comparison signal of the comparator.

Even when the comparison signal of the comparator is reversed from the low level to the high level and/or from the high level to the low level, the noise removal circuit does not immediately reverse the output signal thereof between the low level and the high level according to the comparison signal. Even when the comparison signal is reversed from the low level to the high level and/or from the high level to the low level, only if the comparison signal sustains the level thereof at least over a predetermined time, the output signal is reversed between the low level and high level according to the comparison signal. Therefore, the timer circuit includes the memory means that when the comparison signal of the comparator is reversed from the low level to the high level and/or from the high level to the low level at the first time is verified, is shifted to the memory state in which the fact is stored. When the level of the comparison signal of the comparator is sustained by the second time, the timer circuit reverses an output signal between the low level and high level on the basis of the memory state of the memory means, and then outputs the output signal. However, when the comparison signal of the comparator is reversed during the interval between the first time and second time, the timer circuit regards the fact as a sufficient condition and lifts the memory state of the memory means. Consequently, the comparison signal of the comparator is reversed during the interval between the first time and second time is regarded as the sufficient condition, and a decision can be accurately made that the signal has exhibited the signal change associated with a noise component.

According to the above noise removal circuit, an event that the comparison signal of the comparator is reversed due to a noise component can be accurately grasped. As a result, the comparison signal of the comparator can be continuously monitored. Consequently, the noise removal circuit can produce an output signal by removing the signal change associated with a noise component, from the comparison signal of the comparator.

When the reversal of the comparison signal from the low level to the high level and/or from the high level to the low level at the first time has been verified, the memory means stores a memory signal associated with the reversal. The memory signal is reversed between the low level and high level in order to store a memory state corresponding to the reversal of the comparator signal. When the memory signal is merely reversed between a low level and a high level, a shift to the memory state and lifting thereof can be readily achieved.

A first flip-flop circuit is included that inputs a first clock signal and the comparison signal of the comparator, latches the comparison signal at the first time at which the first clock signal is reversed from the low level to the high level or from the high level to the low level, and outputs the memory signal. After the memory signal is produced, if the comparison signal is reversed during the interval between the first time and second time, the first flip-flop circuit reverses the memory signal between the low level and high level so as to lift the memory state. Using the first flip-flop circuit, the memory means can be readily embodied.

A second flip-flop circuit is further included. The second flip-flop circuit inputs a second clock signal and the memory signal of the first flip-flop circuit, latches an output of the first flip-flop circuit at the second time at which the second clock signal is reversed from the low level to the high level or from the high level to the low level, and outputs an output signal.

According to exemplary embodiments, first, the first flip-flop circuit latches the comparison signal at the first time. If the comparison signal has been reversed from the low level to the high level and/or from the high level to the low level, an output of the first flip-flop circuit representing the memory signal, is reversed, and the memory signal is inputted to the second flip-flop circuit. The second flip-flop circuit latches the memory signal of the first flip-flop circuit at the second time. If the memory signal of the first flip-flop circuit sustains the level thereof from the first time to the second time, the output signal of the second flip-flop circuit is also reversed. Consequently, even when the comparison signal is reversed from the low level to the high level and/or from the high level to the low level, only if the comparison signal sustains the level thereof over at least a predetermined time, such as the interval from the first time to the second time, can the comparison signal be reflected on the output signal. The second clock signal may be produced by reversing the first clock signal.

The timer circuit includes a first timer circuit and a second timer circuit. The first timer circuit inputs the comparison signal of the comparator. After the comparison signal is reversed, for example, from the low level to the high level, if the high level is sustained over at least the predetermined time, the first timer circuit reverses an output signal thereof between the low level and high level, and outputs the output signal. The second timer circuit inputs the comparison signal of the comparator. After the comparison signal is reversed from the high level to the low level, if the low level is sustained over at least the predetermined time, the second timer circuit reverses an output signal thereof between the low level and the high level, and outputs the output signal.

When the timer circuit includes both the first timer circuit and second timer circuit, the timer circuit can handle both a signal change associated with a positive noise component and a signal change associated with a negative noise component. The invention may be embodied in a comparator circuit including the foregoing noise removal circuit. An exemplary comparator circuit includes a comparator that inputs a first input signal and a second input signal, and that, when a difference between the first input signal and second input signal is reversed from a positive value to a negative value or vice versa, reverses the comparison signal between the low level and high level, and outputs the comparison signal. The comparator circuit further includes the aforesaid timer circuit.

For example, when the comparator circuit is adopted as a binary-coding circuit, even if a noise component is superposed on an analog input signal, a signal change associated with the noise component can be removed from the comparison signal of the comparator. The analog input signal can be accurately binary-coded.

According to an exemplary noise removal circuit, an output signal can be produced that is a comparison signal of a comparator having a signal change associated with a noise component removed. Moreover, when the noise removal circuit and comparator are used, a comparator circuit capable of accurately binary-coding an analog input signal can be provided.

The features of various exemplary embodiments will be described as follows. In accordance with a first feature a flip-flop circuit is included that inputs a clock signal and a comparison signal of a comparator, and that latches the comparison signal when the clock signal is reversed. The flip-flop circuit includes a reset terminal, and is reset when the comparison signal of the comparator assumes a low level.

In accordance with a second feature, a flip-flop circuit is included that inputs a clock signal and a comparison signal of a comparator, and that latches the comparison signal when the clock signal is reversed. The flip-flop circuit in accordance with the second feature includes a set terminal, and is set when the comparison signal of the comparator assumes a high level.

In accordance with a third feature, a flip-flop circuit is included that inputs a clock signal and a comparison signal of a comparator, and that latches the comparison signal when the clock signal is reversed. The flip-flop circuit in accordance with a third feature includes a reset terminal, and is reset when the comparison signal of the comparator assumes a high level.

In accordance with a fourth feature, a flip-flop circuit is included that inputs a clock signal and a comparison signal of a comparator, and that latches the comparison signal when the clock signal is reversed. The flip-flop circuit in accordance with a fourth feature includes a set terminal, and is set when the comparison signal of the comparator assumes a low level.

### BRIEF DESCRIPTION OF THE DRAWINGS

Other objects, features and characteristics of the present invention will be appreciated and become apparent to those of ordinary skill in the art and all of which form a part of the present application. In the drawings:

FIG. 1 is a diagram illustrating a configuration of an exemplary binary-coding circuit;

FIG. 2 is a timing diagram illustrating an exemplary timing relevant to a binary-coding circuit;

FIG. 3 is a timing diagram illustrating another exemplary timing relevant to a binary-coding circuit;

FIG. 4 is a timing diagram illustrating still another exemplary timing relevant to a binary-coding circuit;

FIG. 5A is a circuit diagram illustrating exemplary circuitry of a timer circuit;

FIG. 5B is a circuit diagram illustrating other exemplary circuitry of a timer circuit;

FIG. 6A is a timing diagram illustrating exemplary clock signals being produced as single-phase clocks;

FIG. 6B is a timing diagram illustrating exemplary clock signals being produced as two-phase clocks;

FIG. 7 is a timing diagram illustrating exemplary timing relevant to a binary-coding circuit;

FIG. 8 is a timing diagram illustrating another exemplary timing relevant to a binary-coding circuit;

FIG. 9 is a timing diagram illustrating still another exemplary timing relevant to a binary-coding circuit;

FIG. 10 is a circuit diagram illustrating still other exemplary circuitry of a timer circuit;

FIG. 11 is a diagram illustrating still other exemplary circuitry of a timer circuit;

FIG. 12 is a timing diagram illustrating exemplary timing relevant to a timer circuit as in FIG. 11;

FIG. 13 is a diagram illustrating an exemplary peak hold circuit;

FIG. 14 is a timing diagram illustrating exemplary timing relevant to a peak hold circuit as in FIG. 13;

FIG. 15A is a signal diagram illustrating a fluctuation in an analog input signal;

FIG. 15B is a signal diagram illustrating the analog input signal binary-coded by a comparator;

FIG. 15C is a diagram illustrating repetition of reversal and re-reversal of an output of the comparator associated with a noise component; and

FIG. 15D is a diagram illustrating exemplary chattering.

### DETAILED DESCRIPTION OF THE EXEMPLARY EMBODIMENTS

Embodiments of the present invention will be described in further detail with reference to the accompanying drawings. It is to be distinctly understood that the present invention is not limited thereto but may be otherwise variously embodied.

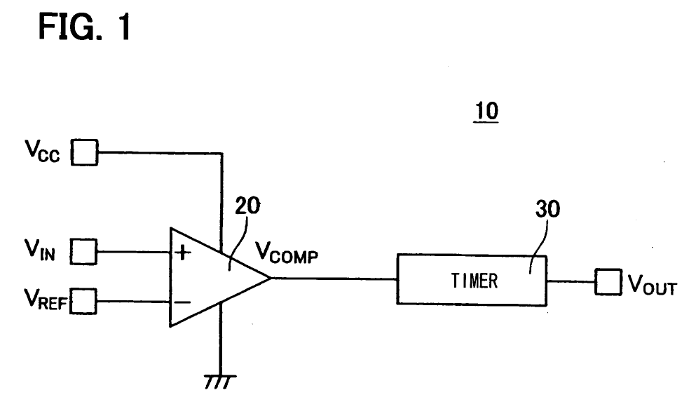

FIG. 1 shows an overall configuration of an exemplary comparator circuit such as a binary-coding circuit 10, which compares an analog input signal V_{IN} with a threshold voltage V_{REF} and outputs an output signal V_{OUT}. The binary-coding circuit 10 includes a comparator 20 and a timer circuit 30.

The comparator 20 has an analog input signal V_{IN} applied to an inverting input terminal thereof, has the threshold voltage V_{REF} applied to a non-inverting input terminal thereof, has a positive potential of a direct-current (DC) supply voltage V_{CC} applied to a positive power connection terminal thereof, and has a negative potential or ground potential of the DC supply voltage V_{CC} applied to a negative power connection terminal thereof. An output terminal of the comparator 20 is connected to the input terminal of the timer circuit 30.

A high-frequency noise component is superposed on the analog input signal V_{IN}, and a comparison signal V_{COMP} of the comparator 20 exhibits a signal change associated with the noise component. The timer circuit 30 discriminates the signal change associated with the noise component, from the comparison signal V_{COMP} of the comparator 20 in terms of a time width, and removes the signal change associated with the noise component, from the comparison signal V_{COMP} of the comparator 20 on the basis of the result of the discrimination. The timer circuit 30 outputs the comparison signal V_{COMP}, from which the signal change associated with the noise component is removed, as an output signal V_{OUT} that is a binary-coded signal.

The timer circuit 30 takes on any of three predetermined time patterns described as follows. The first pattern, (1), involves the signal being reversed from the low level to the high level. After the comparison signal V_{COMP} is reversed from the low level to the high level, if the high level is sustained over at least a predetermined time, the output signal V_{OUT} is reversed from the low level to high level and then outputted. The second pattern, (2), involves the signal being reversed from the high level to the low level. After the comparison signal V_{COMP} is reversed from the high level to the low level, if the low level is sustained over at least a predetermined time, the output signal V_{OUT} is reversed from the high level to the low level and then outputted. The third pattern, (3), involves both the signal being reversed from the low level to the high level and being reversed from the high level to the low level. After the comparison signal V_{COMP} is reversed from the low level to the high level, if the high level is sustained over at least a predetermined time, the output signal V_{OUT} is reversed between the low level and high level and then outputted. Also, after the comparison signal V_{COMP} is reversed from the high level to the low level, if the low level is sustained over at least a predetermined time, the output signal V_{OUT} is reversed between the low level and high level and then outputted. Incidentally, the predetermined times described above may be the same or may be different.

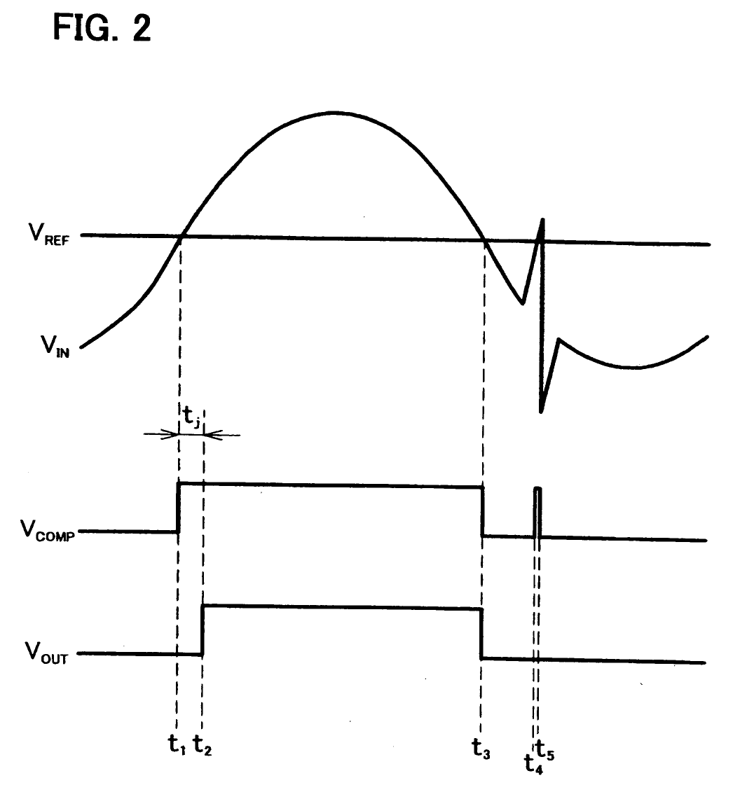

FIG. 2 shows an example of timing relevant to the binary-coding circuit 10 in a case where the timer circuit 30 is of the type associated with the above described pattern (1) described above. In the timing chart of FIG. 2, the analog input signal V_{IN} contains a surge noise component.

At the time t1 when the analog input signal V_{IN} exceeds the threshold voltage V_{REF}, the comparator 20 reverses the comparison signal V_{COMP} from the low level to the high level. At the time t3 when the analog input signal V_{IN} falls below the threshold voltage V_{REF}, the comparator 20 reverses the comparison signal V_{COMP} from the high level to the low level. Moreover, at the time t4, when the analog input signal V_{IN} exceeds the threshold voltage V_{REF} due to the noise component, the comparator 20 reverses the comparison signal V_{COMP} from the low level to the high level. At the time t5, when the analog input signal V_{IN} falls below the threshold voltage V_{REF} due to the noise component, the comparator 20 reverses the comparison signal V_{COMP} from the high level to the low level.

As shown in FIG. 2, even when the comparison signal V_{COMP} of the comparator 20 is reversed from the low level to the high level, the timer circuit 30 does not immediately reverse the output signal V_{OUT} from the low level to the high level according to the comparison signal V_{COMP}. For example, when the comparison signal V_{COMP} is reversed from the low level to the high level, the timer circuit 30 reverses the output signal V_{OUT} from the low level to the high level only if the high level is sustained over at least the predetermined time tⱼ. Consequently, if the high level of the comparison signal V_{COMP} is re-reversed to the low level prior to the elapse of the predetermined time tⱼ, based on, for example, a noise component, after the comparison signal V_{COMP} is reversed from the low level to the high level, the timer circuit 30 does not reverse the output signal V_{OUT} from the low level to the high level before outputting the output signal V_{OUT}.

Namely, the timer circuit 30 discriminates a normal change in the analog input signal V_{IN} from a change due to a high-frequency noise component superposed on the analog input signal based on the time width of the signal change. The normal change in the analog input signal V_{IN} can be characterized as a fluctuation in voltage that occurs over a relatively long period of time compared to the noise signal. The comparison signal V_{COMP} of the comparator 20 also changes in level over a relatively long period of time. When the change is sustained over a relatively long period, the timer circuit 30 decides that a signal change is a normal change in the analog input signal V_{IN} and reverses the output signal V_{OUT} from the low level to the high level. On the other hand, the high-frequency noise component superposed on the analog input signal V_{IN} causes a signal change that makes a complete high-to-low or low-to-high transition that lasts over a relatively short period of time. Therefore, the comparison signal V_{COMP} of the comparator 20 changes in level over a relatively short period of time. In such a case, the timer circuit 30 decides that the signal change is a signal change associated with the high-frequency noise superposed on the analog input signal V_{IN} and does not reverse the output signal V_{OUT}.

As a result of the decision, the timer circuit 30 can produce the output signal V_{OUT} that is the comparison signal V_{COMP} of the comparator 20 with the signal change associated with the noise component removed and the binary-coding circuit 10 can accurately binary-code the analog input signal V_{IN}.

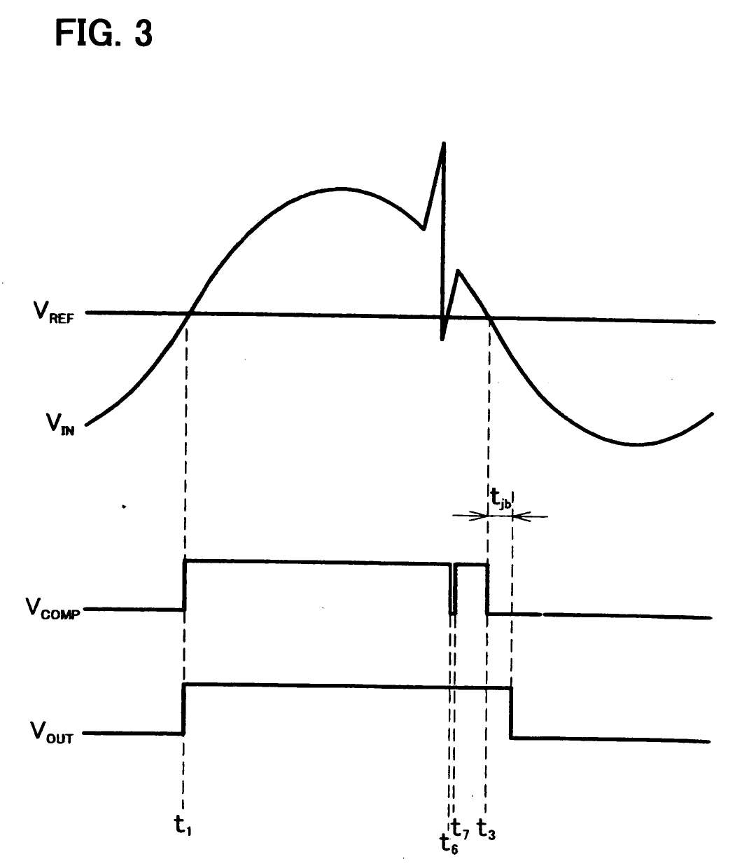

FIG. 3 shows exemplary timing relevant to the binary-coding circuit 10 in a case where the timer circuit 30 is of the type associated with the above described pattern (2). At the time t1, when the analog input signal V_{IN} exceeds the threshold voltage V_{REF}, the comparator 20 reverses the comparison signal V_{COMP} from the low level to the high level. At the time t3, when the analog input signal V_{IN} falls below the threshold voltage V_{REF}, the comparator 20 reverses the comparison signal V_{COMP} from the high level to the low level. At the time t6, when the analog input signal V_{IN} falls below the threshold voltage V_{REF} due to a noise component, the comparator 20 reverses the comparison signal V_{COMP} from the high level to the low level. At the time t7, when the analog input signal V_{IN} exceeds the threshold voltage V_{REF} due to the noise component, the comparator 20 reverses the comparison signal V_{COMP} from the low level to the high level.

As shown in FIG. 3, even when the comparison signal V_{COMP} of the comparator 20 is reversed from the high level to the low level, the timer circuit 30 does not immediately reverse the output signal V_{OUT} from the high level to the low level according to the comparison signal V_{COMP}. After the comparison signal V_{COMP} is reversed from the high level to the low level, the timer circuit 30 reverses the output signal V_{OUT} from the low level to the high level and outputs it only if the low level is sustained at least over a predetermined time t_{jb}. Incidentally, the predetermined time t_{jb} may share the same length with the predetermined time tⱼ in FIG. 2, or may be different.

After the comparison signal V_{COMP} of the comparator 20 is reversed from the high level to the low level, the timer circuit 30 decides that the signal change is a normal change in the analog input signal V_{IN} and reverses the output signal V_{OUT} from the high level to the low level if the low level is sustained at least over the predetermined time t_{jb}. After the comparison signal V_{COMP} of the comparator 20 is reversed from the high level to the low level, the timer circuit 30 decides that the signal change is associated with a high-frequency noise component superposed on the analog input signal V_{IN}, and does not reverse the output signal V_{OUT} if the low level is not sustained at least over the predetermined time t_{jb}.

As a result of the decision, the timer circuit 30 can produce the output signal V_{OUT} that is the comparison signal V_{COMP} of the comparator 20 having the signal change associated with the noise component, removed therefrom. Consequently, the binary-coding circuit 10 can accurately binary-code the analog input signal V_{IN}.

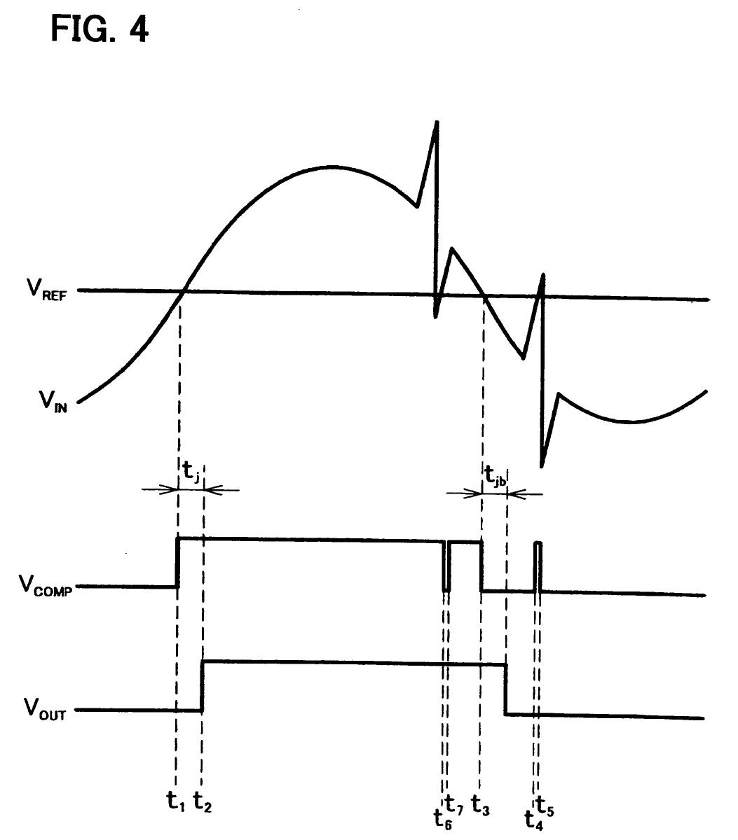

Next, FIG. 4 shows exemplary timing relevant to the binary-coding circuit 10 in a case where the timer circuit 30 is of the type associated with the above described pattern (3) and has the features of both the timer circuit 30 of the type associated with the above described pattern (1) and the timer circuit 30 of the type associated with the above described pattern (2). Consequently, the timer circuit 30 of the type associated with the above described pattern (3) can handle either case where a noise component exceeds the threshold voltage V_{REF} to cause a fluctuation in voltage and a case where the noise component falls below the threshold voltage V_{REF} to cause a fluctuation in voltage.

(First Timer Circuit Example)

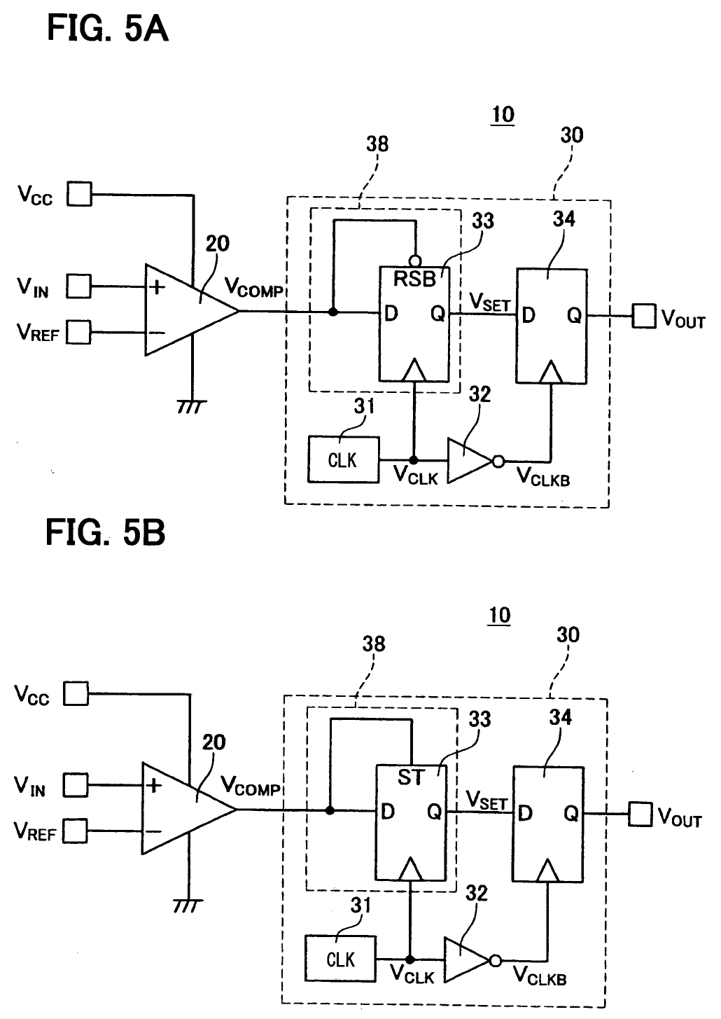

FIG. 5A shows an example of circuitry of the timer circuit 30 of the type associated with the above described pattern (1) while FIG. 5B shows an example of the concrete circuitry of the timer circuit 30 of the type associated with the above described pattern (2). A difference between the timer circuits 30 shown in FIG. 5A and FIG. 5B respectively includes that the timer circuit 30 shown in FIG. 5A has the reverse of the comparison signal V_{COMP} of the comparator 20 applied to the reset terminal of the first flip-flop circuit 33, while the timer circuit 30 shown in FIG. 5B has the comparison signal V_{COMP} of the comparator 20 applied to the set terminal of the first flip-flop circuit 33. As for the other circuit elements, the timer circuits shown in FIG. 5A and FIG. 5B are identical to each other. Hereinafter, the description below will be mainly focused on the timer circuit 30 shown in FIG. 5A.

The timer circuit 30 includes the first flip-flop circuit 33, a second flip-flop circuit 34, a clock circuit 31, and a logical inverter circuit 32. Herein, the first flip-flop circuit 33 can, as described in greater detail hereinafter, temporarily store the state of the comparison signal V_{COMP} of the comparator 20, and therefore acts as a memory means 38. Both the first flip-flop circuit 33 and second flip-flop circuit 34 are D flip-flop circuits.

The comparison signal V_{COMP} of the comparator 20 is applied to the input terminal of the first flip-flop circuit 33. A first clock signal V_{CLK} produced by the clock circuit 31 is applied to the clock terminal of the first flip-flop circuit 33. The reverse of the comparison signal V_{COMP} of the comparator 20 is applied to the reset terminal of the first flip-flop circuit 33. The output terminal of the first flip-flop circuit 33 is connected to the input terminal of the second flip-flop circuit 34.

A second clock signal V_{CLKB} that is the reverse of the first clock signal V_{CLK} produced by the logical inverter circuit 32 is applied to the clock terminal of the second flip-flop circuit 34. The second flip-flop circuit 34 provides an output signal V_{OUT} through the output terminal thereof.

The first flip-flop circuit 33 inputs the first clock signal V_{CLK} and the comparison signal V_{COMP} of the comparator 20, latches the comparison signal V_{COMP} when the first clock signal V_{CLK} is reversed from the low level to the high level, and outputs the comparison signal V_{COMP}. The latched comparison signal V_{COMP} is inputted as a set voltage V_{SET} to the second flip-flop circuit 34.

The second flip-flop circuit 34 inputs the second clock signal V_{CLKB} and the set voltage V_{SET} of the first flip-flop circuit 33, latches the set voltage V_{SET} of the first flip-flop circuit 33 when the second clock signal V_{CLKB} is reversed from the low level to the high level, and outputs the set voltage V_{SET}. The latched set voltage V_{SET} is outputted as the output voltage V_{OUT}.

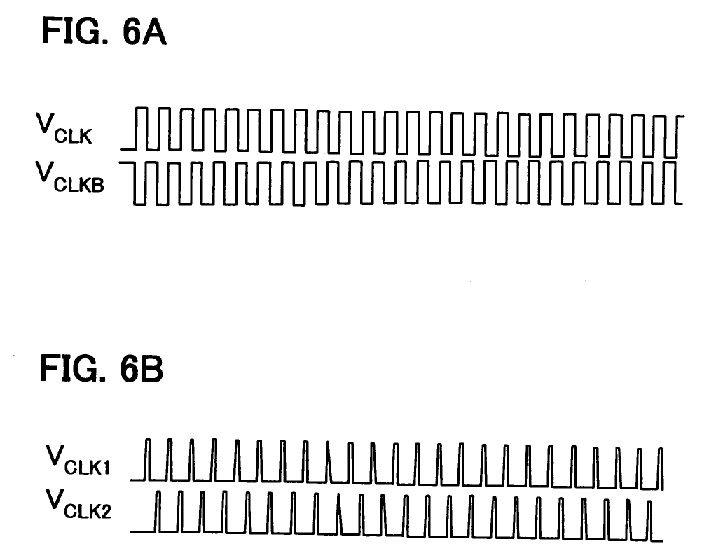

As shown in FIG. 6A, in the present embodiment, the second clock signal V_{CLKB} is produced by reversing the first clock signal V_{CLK}. Thus, the period from the instant the first clock signal V_{CLK} is reversed from the low level to the high level to the instant the second clock signal V_{CLKB} is reversed from the low level to the high level corresponds to a half cycle of the first clock signal V_{CLK}. Alternatively, as shown in FIG. 6B, two-phase clocks, that is, the first clock signal V_{CLK1} and second clock signal V_{CLK2}, which are independently generated, may be employed.

The timer circuit 30 includes the first flip-flop circuit 33. The first flip-flop circuit 33 may be assessed as the memory means 38 because of the capability to store or hold a result. Specifically, when the first clock signal V_{CLK} is reversed from the low level to the high level, if the comparison signal V_{COMP} of the comparator 20 is reversed from the low level to the high level, the first flip-flop circuit 33 may be shifted to a state in which the set voltage V_{SET} is reversed from the low level to the high level in order to store the comparison signal V_{COMP}, which has been reversed from the low level to the high level. The first flip-flop circuit 33 typically has the reverse of the comparison signal V_{COMP} of the comparator 20 applied to the reset terminal thereof. Consequently, when the first flip-flop circuit 33 enters the memory state, the set voltage V_{SET} is immediately reversed from the high level to the low level if the comparison signal V_{COMP} of the comparator 20 is reversed from the high level to the low level. The memory state of the first flip-flop circuit 33 is then lifted.

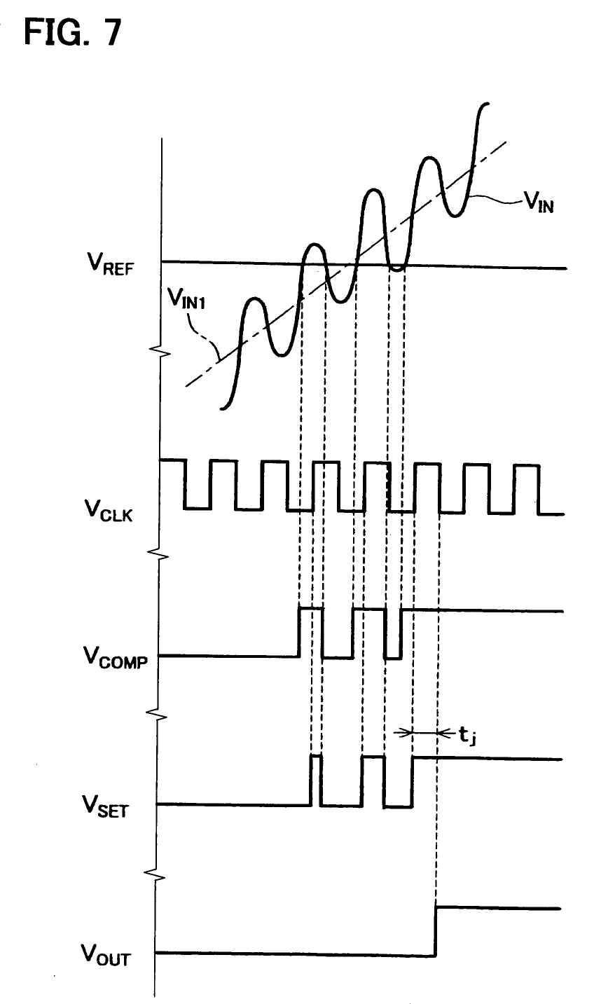

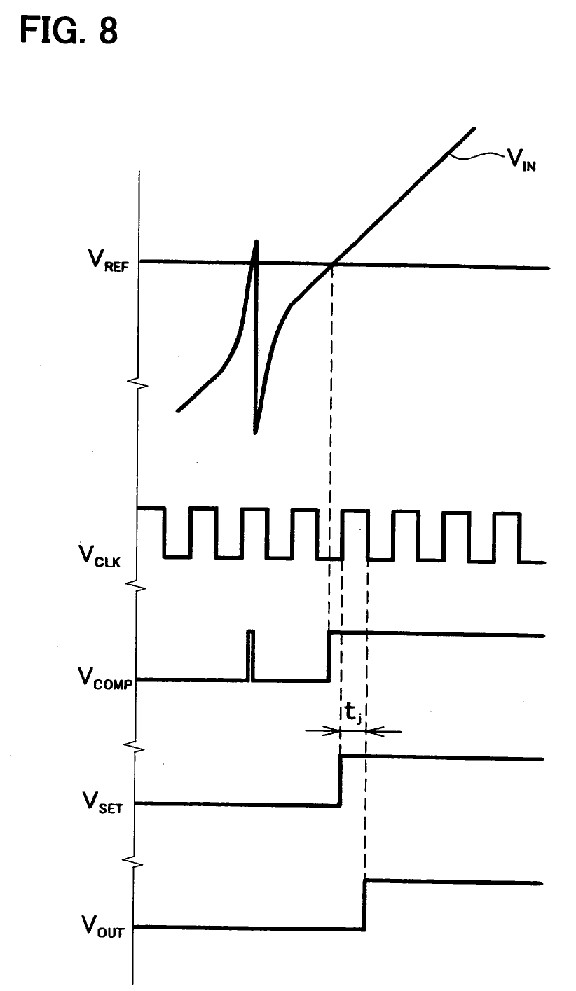

FIG. 7 and FIG. 8 show examples of a timing chart relevant to the binary-coding circuit 10. FIG. 7 shows the example in a case where a pulsating high-frequency noise component is superposed on an analog input signal V_{IN}. FIG. 8 shows the example in a case where a high-frequency surge noise component is superposed on the analog input signal V_{IN}.

As shown in FIG. 7, when the analog input signal V_{IN} on which the pulsating high-frequency noise component is superposed is inputted to the comparator 20, the comparison signal V_{COMP} of the comparator 20 repeats a reverse/re-reverse phenomenon due to the noise component. Therefore, when the noise component is superposed on the analog input signal V_{IN}, the comparison signal V_{COMP} of the comparator 20 exhibits chattering as shown in FIG. 7.

In the timer circuit 30, first, when the first clock signal V_{CLK} is reversed from the low level to the high level, the first flip-flop circuit 30 latches the comparison signal V_{COMP} of the comparator 20. If the comparison signal V_{COMP} has been reversed from the low level to the high level, the set voltage V_{SET} of the first flip-flop circuit 33 is reversed from the low level to the high level, or, in other words, a shift to the memory state is made, and the set voltage V_{SET} is inputted to the second flip-flop circuit 34. When the second clock signal V_{CLK} is reversed from the low level to the high level, that is, the first clock signal V_{CLK} is reversed from the high level to the low level, the second flip-flop circuit 34 latches the set voltage V_{SET} of the first flip-flop circuit 33. If the high level of the set voltage V_{SET} of the first flip-flop circuit 33 is sustained until the first clock signal V_{CLK} is reversed from the low level to the high level and then re-reversed from the high level to the low level over a predetermined time tⱼ, the output signal V_{OUT} of the second flip-flop circuit 34 is reversed from the low level to the high level.

A signal change in the comparison signal V_{COMP} caused by chattering signifies that the signal level of the comparison signal is not sustained over the predetermined time tⱼ. Therefore, the output signal V_{OUT} will not be reversed between the low level and the high level. As a result, the signal change caused by the chattering is removed by the timer circuit 30.

When the foregoing configuration is adopted for the timer circuit 30, the timer circuit 30 can continuously monitor the comparison signal V_{COMP} of the comparator 20. In the timer circuit 30, after the comparison signal V_{COMP} of the comparator 20 is reversed from the low level to the high level, if the comparison signal V_{COMP} is re-reversed from the high level to the low level at least during the predetermined time, a high-level signal is applied to the reset terminal of the first flip-flop circuit 33, and the set voltage V_{SET} of the first flip-flop circuit 33 is immediately reversed from the high level to the low level such that the memory state is removed. In other words, the timer circuit 30 regards the re-reversal of the comparison signal V_{COMP} of the comparator 20 from the high level to the low level during the predetermined time as a sufficient condition to decide that the signal change is associated with a noise component and effectively removes the signal change associated with the noise component.

Referring to FIG. 8, a description will be made of a case where a high-frequency surge noise component is superposed on the analog input signal V_{IN}. When the analog input signal V_{IN} on which a noise component is superposed is inputted to the comparator 20, as shown, the comparison signal V_{COMP} of the comparator 20 is reversed and re-reversed due to the noise component. Consequently, the comparison signal V_{COMP} of the comparator undergoes a signal change associated with the noise component. As noted, the time width of the signal change associated with the noise component is very short. Therefore, the first clock signal V_{CLK} is reversed from the low level to the high level, but the comparison signal V_{COMP} is not reversed from the low level to the high level. Consequently, the set voltage V_{SET} of the first flip-flop circuit 33 sustains the low level, and the signal change associated with the noise component is not reflected on the output signal V_{OUT} and is removed by the timer circuit 30.

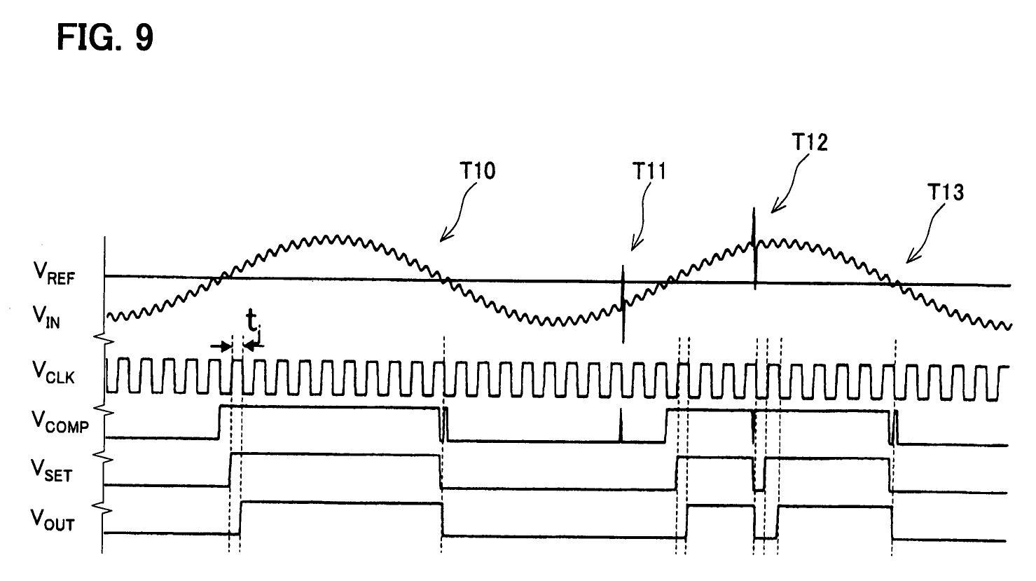

FIG. 9 shows an example of timing relevant to the binary-coding circuit 10 over a longer period of time. At times T10, T11, T12, and T13, comparison signal V_{COMP} of the comparator 20 fluctuates due to a noise component superposed on an analog input signal V_{IN}. At the times T10 and T13, a pulsating high-frequency noise component is superposed on the analog input signal V_{IN}, and the comparison signal V_{COMP} of the comparator 20 fluctuates due to the noise component. At the times T11 and T12, a high-frequency surge noise component is superposed on the analog input signal V_{IN}, and the comparison signal V_{COMP} of the comparator 20 fluctuates due to the noise component.

As mentioned above, at the times T10, T11, and T13, a noise component exceeds the threshold voltage V_{REF} to cause a fluctuation in voltage. A signal change associated with the noise component is not reflected on the output signal V_{OUT}. The comparator 30 succeeds in removing the signal change associated with the noise component. The timer circuit 30 of the type associated with the above described pattern (1) cannot handle a case where a noise component falls below the threshold voltage V_{REF} to cause a fluctuation in voltage, for example, as at the time T12. The circuitry capable of handling such a case will be described in greater detail hereinafter.

(Second Timer Circuit Example)

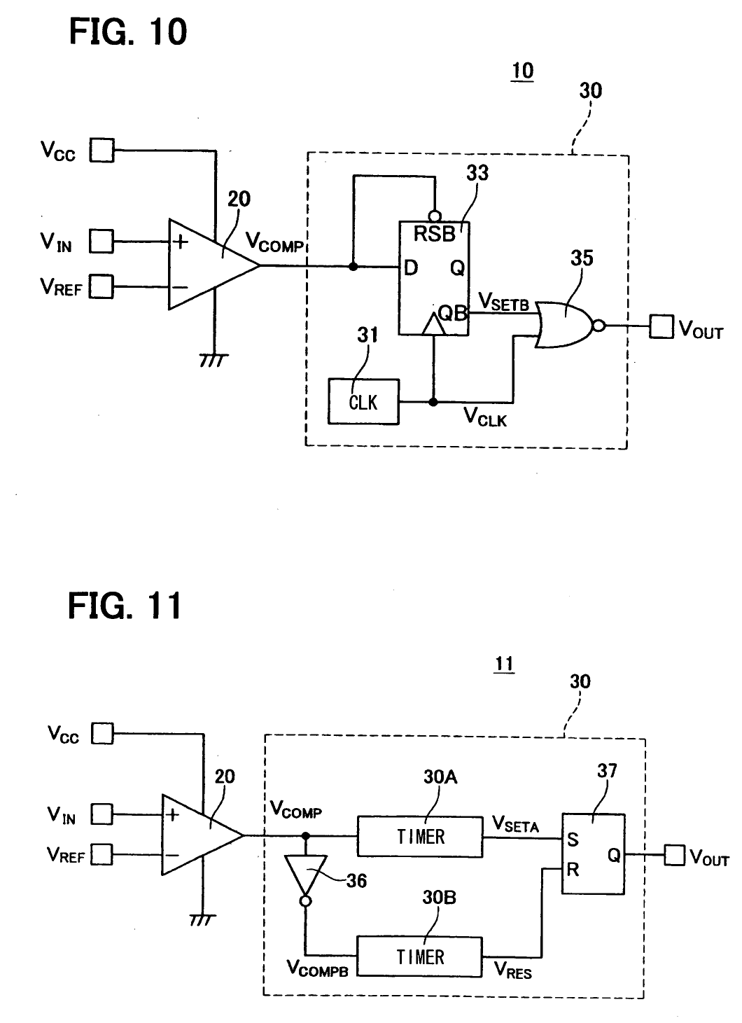

FIG. 10 shows another example of the circuitry of the timer circuit 30 of the type associated with the above described pattern (1). The timer circuit 30 includes a first flip-flop circuit 33, a logical NOR circuit 35, and a clock circuit 31. The first flip-flop circuit 33 is a D flip-flop circuit.

The comparison signal V_{COMP} of the comparator 20 is applied to the input terminal of the first flip-flop circuit 33. A clock signal V_{CLK} produced by the clock circuit 31 is applied to the clock terminal of the first flip-flop circuit 33. The reverse of the comparison signal V_{COMP} of the comparator 20 is applied to the reset terminal of the first flip-flop circuit 33. The inverting output terminal of the first flip-flop circuit 33 is connected to one of the input terminals of the logical NOR circuit 35. The clock signal V_{CLK} is applied to the other input terminal of the logical NOR circuit 35.

The first flip-flop circuit 33 inputs the clock signal V_{CLK} and the comparison signal V_{COMP} of the comparator 20. When the clock signal V_{CLK} is reversed from the low level to the high level, the first flip-flop circuit 33 latches the comparison signal V_{COMP}, and outputs the result of the reversal. The reversed output voltage of the first flip-flop circuit 33 is applied as a reverse set voltage V_{SETB} to one of the input terminals of the logical NOR circuit 35.

The logical NOR circuit 35 inputs the clock signal V_{CLK} and the reverse set voltage V_{SETB} of the first flip-flop circuit 33. When the clock signal V_{CLK} is reversed from the high level to the low level, if the reverse set voltage V_{SETB} assumes the low level, the logical NOR circuit 35 reverses the output signal V_{OUT} from the low level to the high level.

According to the timer circuit 30, first, when the clock signal V_{CLK} is reversed from the low level to the high level, the first flip-flop circuit 33 latches the comparison signal V_{COMP}. If the comparison signal V_{COMP} has been reversed from the low level to the high level, the output of the first flip-flop circuit 33 through the inverting output terminal thereof is reversed from the high level to the low level, and the reverse set voltage V_{SETB} is applied to one of the terminals of the logical NOR circuit 35. Thereafter, assuming that the reverse set voltage V_{SETB} of the first flip-flop circuit 33 sustains the low level until the clock signal V_{CLK} is reversed from the high level to the low level, when the clock signal V_{CLK} is reversed from the high level to the low level, the output of the logical NOR circuit 35 is reversed from the low level to the high level.

Consequently, only when the comparison signal V_{COMP} sustains the level over a predetermined time such as a half cycle of the clock signal V_{CLK}, the comparison signal V_{COMP} is reflected on the output signal V_{OUT}. Since the reversal of comparison signal V_{COMP} due to a noise component is not reflected on the output signal V_{OUT} the noise component is effectively removed.

(Third Timer Circuit Example)

FIG. 11 shows the overall configuration of a binary-coding circuit 11 of the type associated with the above described pattern (3). The same reference numerals are assigned to the same components shared with the binary-coding circuit 10 shown in FIG. 5, and the description of the components will be omitted.

The timer circuit 30 of the binary-coding circuit 11 includes a first timer circuit 30A and a second timer circuit 30B. Both the first timer circuit 30A and second timer circuit 30B are realized with the timer circuit of the type associated with the above described pattern (1). For example, in the present embodiment, both the first timer circuit 30A and second timer circuit 30B can be realized with the timer circuit 30 shown in FIG. 5A. The comparison signal V_{COMP} of the comparator 20 is reversed by a logical inverter circuit 36, and inputted to the timer circuit 30B shown in FIG. 11. Consequently, when the timer circuit 30B is used in combination with the logical inverter circuit 36, the timer circuit 30B is assessed as the timer circuit of the type associated with the above described pattern (2). The output voltage V_{SET} of the timer circuit 30A is applied to the set terminal of an SR flip-flop circuit 37, and the output voltage V_{RES} of the timer circuit 30B is applied to the reset terminal of the SR flip-flop circuit 37. When the output voltage V_{SETA} of the first timer circuit 30A has been reversed from the low level to the high level, the SR flip-flop circuit 37 reverses the output signal V_{OUT} from the low level to the high level, and outputs the output signal V_{OUT}. When the output voltage V_{RES} of the second timer circuit 30B has been reversed from the low level to the high level, the SR flip-flop circuit reverses the output signal V_{OUT} from the high level to the low level, and outputs the output signal V_{OUT}.

The timer circuit 30 shown in FIG. 11 characteristically has the same features as those of the timer circuit of the type associated with the above described pattern (1) and the timer circuit of the type associated with the above described pattern (2).

The first timer circuit 30A inputs the comparison signal V_{COMP} of the comparator 20. Moreover, after the comparison signal V_{COMP} is reversed from the low level to the high level, if the high level is sustained at least over a predetermined time, the output voltage V_{SETA} is reversed by the first timer circuit 30A from the low level to the high level and applied to the set terminal of the SR flip-flop circuit 37. When the output voltage V_{SETA} is reversed from the low level to the high level, the output signal V_{OUT} is reversed by the SR flop-flop circuit 37 from the low level to the high level and output.

The second timer circuit 30B inputs the comparison signal V_{COMP} of the comparator 20, which has been reversed by the logical inverter circuit 36. Consequently, after the comparison signal V_{COMP} is reversed from the high level to the low level, if the low level is sustained at least over a predetermined time, the output voltage V_{RES} is reversed by the second timer circuit 30B from the low level to the high level and applied to the reset terminal of the SR flip-flop circuit 37. When the output voltage V_{RES} is reversed from the low level to the high level, the output signal V_{OUT} is reversed by the SR flip-flop circuit 37 from the high level to the low level and output.

Consequently, a signal change associated with a noise component exceeding the threshold voltage V_{REF} is removed from the comparison signal V_{SETA}. The comparison signal V_{SETA} is applied to the set terminal of the SR flip-flop circuit 37. Based on the comparison signal V_{COMP}, that is, when the comparison signal V_{COMP} is reversed from the low level to the high level, the output signal V_{OUT} is reversed by the SR flop-flop circuit 37 from the low level to the high level and output. Further, a signal change associated with a noise component falling below the threshold voltage V_{REF} is removed from the comparison signal V_{RES}. The comparison signal V_{RES} is then applied to the reset terminal of the SR flip-flop circuit 37. Based on the comparison signal V_{COMP}, that is, when the comparison signal V_{COMP} is reversed from the high level to the low level, the output signal V_{OUT} is reversed by the SR flop-flop circuit 37 from the high level to the low level and outputs. A typical signal change in the comparison signal V_{COMP} that exceeds the threshold voltage V_{REF} causes the output signal V_{OUT} to be reversed by the SR flip-flop circuit 37 from the low level to the high level and output. A typical signal change in the comparison signal V_{COMP} that falls below the threshold voltage V_{REF}, causes the output signal V_{OUT} to be reversed by the SR flip-flop circuit 37 from the high level to the low level and output.

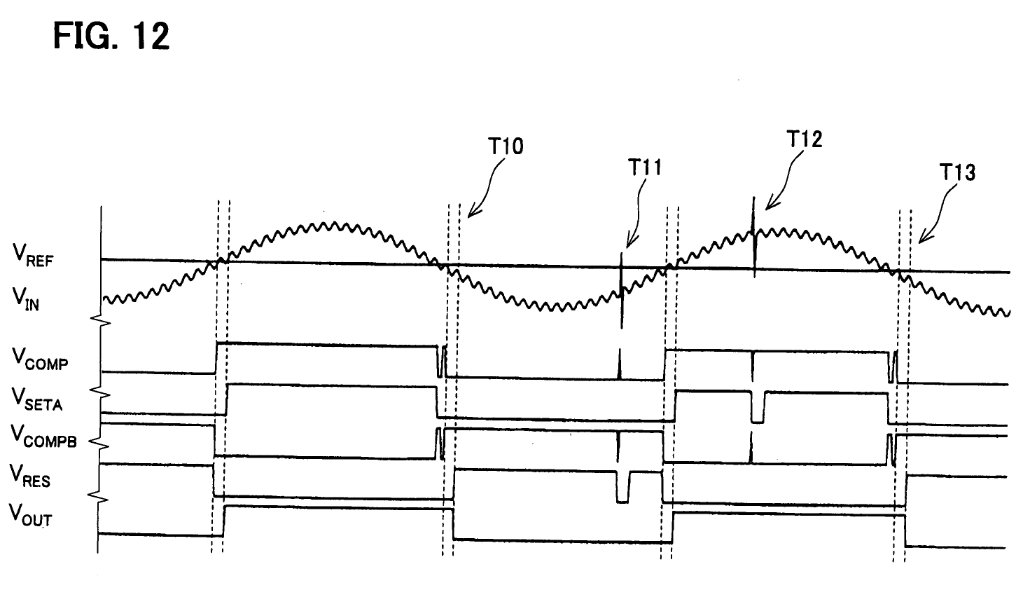

FIG. 12 shows a timing chart relevant to the binary-coding circuit 11 shown in FIG. 11 and noise components of different types. At times T10, T11, T12, and T13, a noise component is contained in the analog input signal V_{IN}. At the times T10 and T13, a pulsating high-frequency noise component is superposed on the analog input signal V_{IN}. At the times T11 and T12, a high-frequency surge noise component is superposed on the analog input signal V_{IN}.

When both the first timer circuit 30A and second timer circuit 30B are included, both a case where a fluctuation in the comparison signal V_{COMP} associated with a noise component exceeds the threshold voltage V_{REF} and a case where the fluctuation falls below the threshold voltage V_{REF} can be coped with. Consequently, at any of the times T10, T11, T12, and T13, the output signal V_{OUT} having a noise component removed therefrom can be provided.

As shown in FIG. 12, at the times T10, T11, T12, and T13, the comparison signal V_{COMP} of the comparator 20 fluctuates due to a noise component superposed on the analog input signal V_{IN}. At the times T10 and T13, a pulsating high-frequency noise component is superposed on the analog input signal V_{IN}, and the comparison signal V_{COMP} of the comparator 20 fluctuates due to the noise component. At the times T11 and T12, a high-frequency surge noise component is superposed on the analog input signal V_{IN}, and the comparison signal V_{COMP} of the comparator 20 fluctuates due to the above described noise component.

At the times T10, T11, and T13, when a noise component exceeds the threshold voltage V_{REF} a fluctuation in voltage takes place. At the time T12, when a noise component falls below the threshold voltage V_{REF} a fluctuation in voltage takes place. In the binary-coding circuit 11 shown in FIG. 11, at the times T10, T11, T12, and T13, a signal change associated with a noise component is not reflected on the output signal V_{OUT}. The comparator circuit 30 succeeds in removing the signal change associated with a noise component.

### (Example of a Peak Hold Circuit)

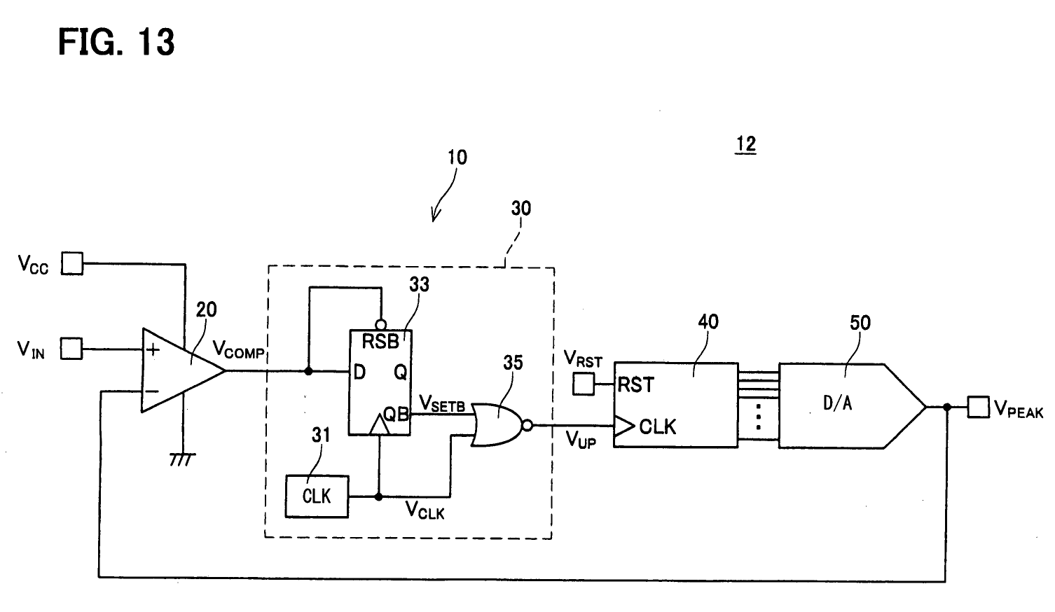

As shown in FIG. 13 the binary-coding circuit 10 can be adapted to circuitry of a positive peak hold circuit 12. The peak hold circuit 12 includes a comparator 20, a timer circuit 30, a counter circuit 40, and a digital-to-analog (D/A) conversion circuit 50. In the present example, the circuit shown in FIG. 5B is adopted as the timer circuit 30. Alternatively, the circuit shown in FIG. 5A may be adopted as the timer circuit 30.

The counter circuit 40 is an up/down n-bit counter circuit. The output signal V_{UP} of the timer circuit 30 is applied to the up input terminal of the counter circuit 40. The counter circuit 40 has a reset input terminal, and a reset signal V_{RST} is applied to the input terminal. When the output signal V_{UP} of the timer circuit 30 is reversed from the low level to the high level, the counter circuit 40 increments a counter value.

The D/A conversion circuit 50 outputs a voltage associated with the counter value of the counter circuit 40. The output of the D/A conversion circuit 50 is used as a positive peak voltage V_{PEAK} of an input voltage V_{IN}, and is applied to the inverting input terminal of the comparator 20.

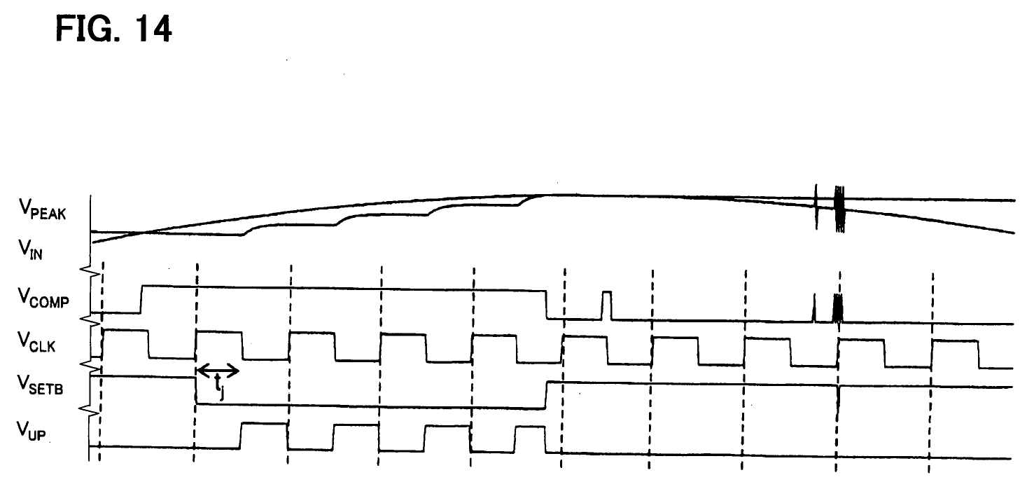

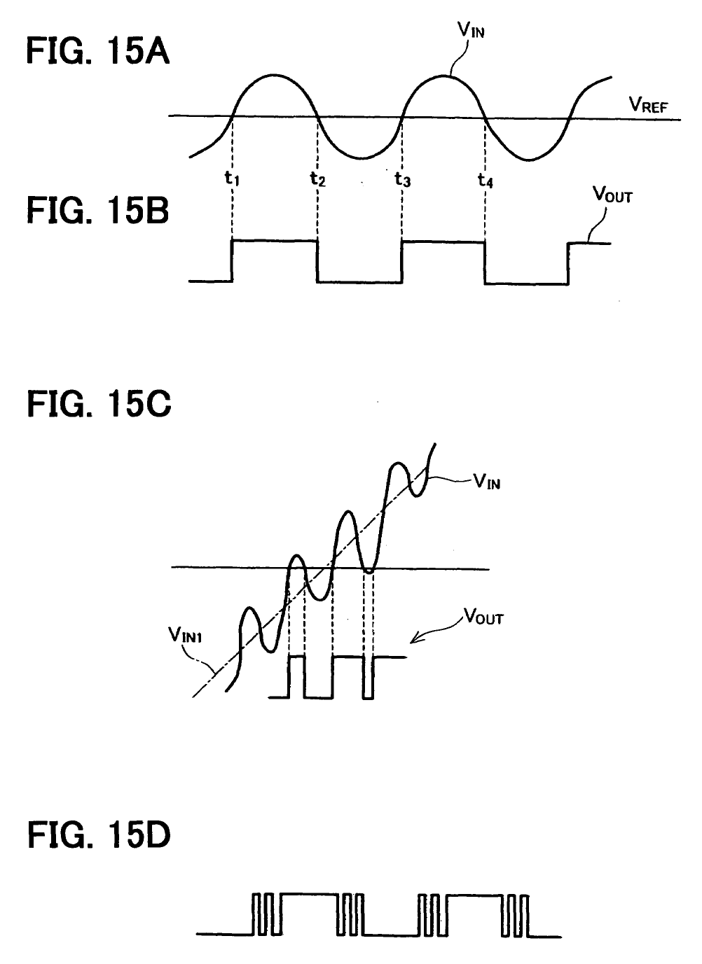

FIG. 14 is an operating waveform diagram concerning a peak voltage detection circuit 10 that is the binary-coding circuit 10. When the measurement by the peak hold circuit 12 is initiated, a reset signal V_{RST} is inputted to the counter circuit 40, and the counter value of the counter circuit 40 is initialized. When the counter value of the counter circuit 40 is initialized, an output voltage V_{PEAK} of the D/A conversion circuit 50 is also initialized. As shown in FIG. 14, when the input voltage V_{IN} exceeds the output voltage V_{PEAK}, the comparison signal V_{COMP} of the comparator 20 is reversed from the low level to the high level. In the timer circuit 30, when the clock signal V_{CLK} is reversed from the low level to the high level, the first flip-flop circuit 33 latches the comparison signal V_{COMP}. At such a time, since the comparison signal V_{COMP} is reversed from the low level to the high level, the output of the first flip-flop circuit 33 through the inverting output terminal thereof is reversed from the high level to the low level. The reverse set voltage V_{SETB} is applied to one of the terminals of the logical NOR circuit 35.

Since the reverse set voltage V_{SETB} of the first flip-flop circuit 33 sustains the low level until the clock signal V_{CLK} is reversed from the high level to the low level, when the clock signal V_{CLK} is reversed from the high level to the low level, the output signal V_{UP} of the logical NOR circuit 35 is reversed from the low level to the high level. When the output signal V_{UP} of the timer circuit 30 is reversed from the low level to the high level, the counter circuit 40 increments the counter value. Consequently, the output voltage V_{PEAK} of the D/A conversion circuit 50 rises synchronously in a stepwise manner with the reversal of the output signal V_{UP} of the timer circuit 30 from the low level to the high level.

When the output voltage V_{PEAK} reaches the input voltage V_{IN} and the input voltage V_{IN} falls below the output voltage V_{PEAK}, the output signal V_{COMP} of the comparator 20 is reversed from the high level to the low level. At the same time, the output of the first flip-flop circuit 33 through the inverting output terminal thereof is reversed from the low level to the high level. As a result, the output of the logical NOR circuit 35 sustains the low level, and the counter circuit 40 ceases incrementing the counter value, and the rise of the output voltage V_{PEAK} also ceases. Through these pieces of processing, the peak hold circuit 12 detects the positive peak value of the input voltage V_{IN}.

Various exemplary embodiments of the present invention have been described so far. However, the above described embodiments are mere examples and are not intended to limit or restrict the application of the claims. Further, the claims appended hereto are also intended to encompass various variants or modifications of the exemplary embodiments discussed and described herein.

Moreover, the technical elements described in this specification or the appended drawings exert technical usefulness solely or in combination. The combination of the technical elements is not restricted solely to the combinations set forth in the claims appended hereto. Moreover, while, as described and illustrated herein, it is possible to accomplish multiple objects simultaneously, by accomplishing even one of the objects, usefulness is achieved.

What is claimed is:

1. A noise removal circuit for removing a signal change associated with a noise component present in a comparison signal outputted from a comparator from an output signal, the comparator inputting a first input signal and a second input signal, the noise removal circuit comprising:
a timer circuit configured to:
input the comparison signal;
verifies that the comparison signal is reversed according to one of from a low comparison level to a high comparison level and from the high comparison level to the low comparison level at a first time and at a second time later than the first time; and
reverses the output signal according to the one and outputs the output signal after the reversal of the comparison signal is verified according to the one if the reversal of the comparison signal is sustained from the first time to the second time; and
a memory means that sets a memory state corresponding to the reversal according to the one at the first time when the reversal according to the one at the first time is verified,
wherein if the comparison signal is reversed during the interval between the first time and the second time, the memory state of the memory means is cleared.

2. The noise removal circuit according to claim 1, wherein:
when the memory means sets the memory state corresponding to the reversal according to the one at the first time when the reversal according to the one at the first time is verified, the memory means produces a memory signal; and
the memory signal is reversed in order to set the memory state.

3. The noise removal circuit according to claim 2, further comprising a first flip-flop circuit configured to:
input a first clock signal and the comparison signal of the comparator;
latches the comparison signal when the first clock signal is reversed according to one of from a first low clock level to a first high clock level and from the first high clock level to the first low clock level; and
outputs the memory signal;
wherein after the memory signal is produced, the first flip-flop circuit reverses the memory signal so as to clear the memory state if the comparison signal is reversed during the interval between the first time and the second time.

4. The noise removal circuit according to claim 3, further comprising a second flip-flop circuit configured to:
input a second clock signal and the memory signal of the first flip-flop circuit;
latch the output of the first flip-flop circuit when the second clock signal is reversed according to one of from a low second clock level to a high second clock level and from the high second clock level to the low second clock level; and
output the output signal.

5. The noise removal circuit according to claim 4, wherein the second clock signal is reversed relative to the first clock signal.

6. The noise removal circuit according to claim 1, wherein the timer circuit includes:
a first timer circuit configured to:
input the comparison signal of the comparator;
reverses the output signal based on the one being from the low comparison level to the high comparison level after the comparison signal is reversed according to the one if the reversal according to the one is sustained at least over a predetermined time; and
outputs the output signal; and
a second timer circuit configured to:
input the comparison signal of the comparator;
reverse the output signal based on the one being from the high comparison level to the low comparison level after the comparison signal is reversed according to the one if the reversal according to the one is sustained at least over the predetermined time; and
outputs the output signal.

7. A comparator circuit comprising:
a comparator configured to:
input a first input signal and a second input signal;
reverse a comparison signal output from the comparator and output the comparison signal when a difference between the first input signal and second input signal is reversed; and
a timer circuit configured to:
input the comparison signal;
verify that the comparison signal is reversed at a first time and at a second time later than the first time; and
reverse an output signal and output the output signal after the comparison signal is reversed if the reversal of the comparison signal is sustained from the first time to the second time, wherein:
the timer circuit includes a memory means configured to:
store a memory state corresponding to the reversal of the comparison signal when the reversal of the comparison signal at the first time is verified; and
clear the memory state if the comparison signal is reversed during the interval between the first time and second time.

8. The comparator circuit according to claim 7, wherein:
when the reversal of comparison signal at the first time is verified, the memory means produces a memory signal; and
the memory signal is reversed in order to store the memory state.

9. The comparator circuit according to claim 8, wherein:
the memory means includes a first flip-flop circuit configured to:
input a first clock signal and the comparison signal of the comparator,
latch the comparison signal when the first clock signal is reversed; and
output the memory signal;
after the memory signal is produced, when the comparison signal is reversed during the interval between the first time and second time, the first flip-flop circuit reverses the memory signal so as to clear the memory state.

10. The comparator circuit according to claim 9, wherein the timer circuit further includes a second flip-flop circuit configured to:
input a second clock signal and the memory signal of the first flip-flop circuit;
latch the output of the first flip-flop circuit when the second clock signal is reversed; and
output the output signal.

11. The comparator circuit according to claim 10, wherein the second clock signal is reversed relative to the first clock signal.

12. The comparator circuit according to claim 7, wherein the timer circuit includes:
a first timer circuit that inputs the comparison signal of the comparator, that after the comparison signal is reversed from the low level to the high level, if the high level is sustained at least over a predetermined time, reverses an output signal between the low level and high level, and outputs the output signal; and
a second timer circuit that inputs the comparison signal of the comparator, that after the comparison signal is reversed from the high level to the low level, if the low level is sustained at least over the predetermined time, reverses an output signal between the low level and high level and outputs the output signal.
